(19) United States
(12) Patent Application Publication
(10) Pub. No.: US 2024/0072169 A1
(43) Pub. Date: Feb. 29, 2024

(54) TRANSISTOR, INTEGRATED CIRCUIT, AND MANUFACTURING METHOD OF TRANSISTOR

(71) Applicant: Taiwan Semiconductor Manufacturing Company, Ltd., Hsinchu (TW)

(72) Inventors: Marcus Johannes Henricus Van Dal, Linden (BE); Gerben DOORNBOS, Kessel-Lo (BE)

(73) Assignee: Taiwan Semiconductor Manufacturing Company, Ltd., Hsinchu (TW)

(21) Appl. No.: 17/896,093

(22) Filed: Aug. 26, 2022

(51) Int. Cl. H01L 29/78; H01L 29/417; H01L 29/66; H01L 29/786

(52) U.S. Cl. CPC H01L 29/78391; H01L 29/41733; H01L 29/66969; H01L 29/78648; H01L 29/7869

(57) ABSTRACT

A transistor includes a first gate electrode, a ferroelectric layer, a channel layer, a second gate electrode, and a hole supply layer. The ferroelectric layer is disposed over the first gate electrode. The channel layer is disposed on the ferroelectric layer. The second gate electrode is disposed over the channel layer. The hole supply layer is located between the second gate electrode and the channel layer. An electron trap density of the hole supply layer is higher than an electron trap density of the channel layer.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an integrated circuit in accordance with some embodiments of the disclosure.

FIG. 2A to FIG. 2H are top views illustrating various stages of a manufacturing method of the second transistor in FIG. 1.

FIG. 3A to FIG. 3H are cross-sectional views illustrating various stages of the manufacturing method of the second transistor in FIG. 2A to FIG. 2H.

FIG. 4A is a top view of a second transistor in accordance with some alternative embodiments of the disclosure.

FIG. 4B is a cross-sectional view of the second transistor in FIG. 4A.

FIG. 5A is a top view of a second transistor in accordance with some alternative embodiments of the disclosure.

FIG. 5B is a cross-sectional view of the second transistor in FIG. 5A.

FIG. 6A to FIG. 6J are top views illustrating various stages of a manufacturing method of the second transistor in accordance with some alternative embodiments of the disclosure.

FIG. 7A to FIG. 7J are cross-sectional views illustrating various stages of the manufacturing method of the second transistor in FIG. 6A to FIG. 6J.

FIG. 8A is a top view of a second transistor in accordance with some alternative embodiments of the disclosure.

FIG. 8B is a cross-sectional view of the second transistor in FIG. 8A.

FIG. 9A to FIG. 9F are top views illustrating various stages of a manufacturing method of the second transistor in accordance with some alternative embodiments of the disclosure.

FIG. 10A to FIG. 10F are cross-sectional views illustrating various stages of the manufacturing method of the second transistor in FIG. 9A to FIG. 9F.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

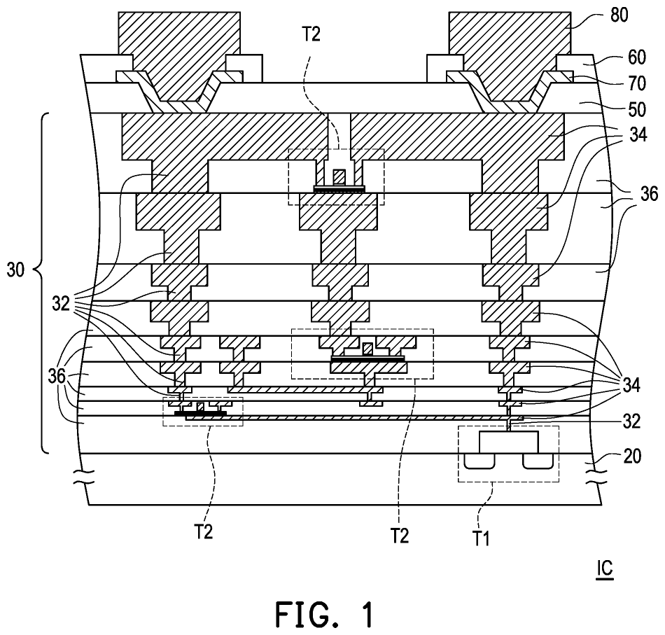

FIG. 1 is a schematic cross-sectional view of an integrated circuit in accordance with some embodiments of the disclosure. In some embodiments, the integrated circuit IC includes a substrate 20, an interconnect structure 30, a passivation layer 50, a post-passivation layer 60, a plurality of conductive pads 70, and a plurality of conductive terminals 80. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. In some embodiments, these doped regions serve as source/drain regions of a first transistor T1, which is over the substrate 20. Depending on the types of the dopants in the doped regions, the first transistor T1 may be referred to as n-type transistor or p-type transistor. In some embodiments, the first transistor T1 further includes a metal gate and a channel under the metal gate. The channel is located between the source region and the drain region to serve as a path for electron to travel when the first transistor T1 is turned on. On the other hand, the metal gate is located above the substrate 20 and is embedded in the interconnect structure 30. In some embodiments, the first transistor T1 is formed using suitable Front-end-of-line (FEOL) process. For simplicity, one first transistor T1 is shown in FIG. 1. However, it should be understood that more than one first transistors T1 may be presented depending on the application of the integrated circuit IC. When multiple first transistors T1 are presented, these first transistors T1 may be separated by shallow trench isolation (STI; not shown) located between two adjacent first transistors T1.

As illustrated in FIG. 1, the interconnect structure 30 is disposed on the substrate 20. In some embodiments, the interconnect structure 30 includes a plurality of conductive vias 32, a plurality of conductive patterns 34, a plurality of dielectric layers 36, and a plurality of second transistors T2. As illustrated in FIG. 1, the conductive patterns 34 and the conductive vias 32 are embedded in the dielectric layers 36. In some embodiments, the conductive patterns 34 located at different level heights are connected to one another through the conductive vias 32. In other words, the conductive patterns 34 are electrically connected to one another through the conductive vias 32. In some embodiments, the bottommost conductive vias 32 are connected to the first transistor T1. For example, the bottommost conductive vias 32 are connected to the metal gate, which is embedded in the bottommost dielectric layer 36, of the first transistor T1. In other words, the bottommost conductive vias 32 establish electrical connection between the first transistor T1 and the conductive patterns 34 of the interconnect structure 30. It should be noted that in some alternative cross-sectional views, other bottommost conductive vias 32 are also connected to the source/drain regions of the first transistor T1. That is, in some embodiments, the bottommost conductive vias 32 may be referred to as “contact structures” of the first transistor T1.

In some embodiments, a material of the dielectric layers 36 includes polyimide, epoxy resin, acrylic resin, phenol resin, benzocyclobutene (BCB), polybenzoxazole (PBO), or any other suitable polymer-based dielectric material. Alternatively, the dielectric layers 36 may be formed of oxides or nitrides, such as silicon oxide, silicon nitride, aluminum oxide, hafnium oxide, hafnium zirconium oxide, or the like. In some embodiments, different dielectric layers 36 are formed by the same material. However, the disclosure is not limited thereto. In some alternative embodiments, different dielectric layers 36 may be formed by different materials. The dielectric layers 36 may be formed by suitable fabrication techniques, such as spin-on coating, chemical vapor deposition (CVD), plasma-enhanced chemical vapor deposition (PECVD), or the like.

In some embodiments, a material of the conductive patterns 34 and the conductive vias 32 includes aluminum, titanium, copper, nickel, tungsten, or alloys thereof. The conductive patterns 34 and the conductive vias 32 may be formed by electroplating, deposition, and/or photolithography and etching. In some embodiments, the conductive patterns 34 and the underlying conductive vias 32 are formed simultaneously. It should be noted that the number of the dielectric layers 36, the number of the conductive patterns 34, and the number of the conductive vias 32 illustrated in FIG. 1 are merely for illustrative purposes, and the disclosure is not limited thereto. In some alternative embodiments, fewer or more layers of the dielectric layers 36, the conductive patterns 34, and/or the conductive vias 32 may be formed depending on the circuit design.

In some embodiments, the second transistors T2 are embedded in the interconnect structure 30. For example, the second transistors T2 are embedded in the dielectric layers 36. In some embodiments, the second transistors T2 are electrically connected to the conductive patterns 34 through the corresponding conductive vias 32. The formation method and the structure of the second transistors T2 will be described in detail later.

As illustrated in FIG. 1, the passivation layer 50, the conductive pads 70, the post-passivation layer 60, and the conductive terminals 80 are sequentially formed on the interconnect structure 30. In some embodiments, the passivation layer 50 is disposed on the topmost dielectric layer 36 and the topmost conductive patterns 34. In some embodiments, the passivation layer 50 has a plurality of openings partially exposing each topmost conductive pattern 34. In some embodiments, the passivation layer 50 is a silicon oxide layer, a silicon nitride layer, a silicon oxynitride layer, or a dielectric layer formed by other suitable dielectric materials. The passivation layer 50 may be formed by suitable fabrication techniques, such as high density plasma chemical vapor deposition (HDP-CVD), PECVD, or the like.

In some embodiments, the conductive pads 70 are formed over the passivation layer 50. In some embodiments, the conductive pads 70 extend into the openings of the passivation layer 50 to be in direct contact with the topmost conductive patterns 34. That is, the conductive pads 70 are electrically connected to the interconnect structure 30. In some embodiments, the conductive pads 70 include aluminum pads, copper pads, titanium pads, nickel pads, tungsten pads, or other suitable metal pads. The conductive pads 70 may be formed by, for example, electroplating, deposition, and/or photolithography and etching. It should be noted that the number and the shape of the conductive pads 70 illustrated in FIG. 1 are merely for illustrative purposes, and the disclosure is not limited thereto. In some alternative embodiments, the number and the shape of the conductive pad 70 may be adjusted based on demand.

In some embodiments, the post-passivation layer 60 is formed over the passivation layer 50 and the conductive pads 70. In some embodiments, the post-passivation layer 60 is formed on the conductive pads 70 to protect the conductive pads 70. In some embodiments, the post-passivation layer 60 has a plurality of contact openings partially exposing each conductive pad 70. The post-passivation layer 60 may be a polyimide layer, a PBO layer, or a dielectric layer formed by other suitable polymers. In some embodiments, the post-passivation layer 60 is formed by suitable fabrication techniques, such as HDP-CVD, PECVD, or the like.

As illustrated in FIG. 1, the conductive terminals 80 are formed over the post-passivation layer 60 and the conductive pads 70. In some embodiments, the conductive terminals 80 extend into the contact openings of the post-passivation layer 60 to be in direct contact with the corresponding conductive pad 70. That is, the conductive terminals 80 are electrically connected to the interconnect structure 30 through the conductive pads 70. In some embodiments, the conductive terminals 80 are conductive pillars, conductive posts, conductive balls, conductive bumps, or the like. In some embodiments, a material of the conductive terminals 80 includes a variety of metals, metal alloys, or metals and mixture of other materials. For example, the conductive terminals 80 may be made of aluminum, titanium, copper, nickel, tungsten, tin, and/or alloys thereof. The conductive terminals 80 are formed by, for example, deposition, electroplating, screen printing, or other suitable methods. In some embodiments, the conductive terminals 80 are used to establish electrical connection with other components (not shown) subsequently formed or provided.

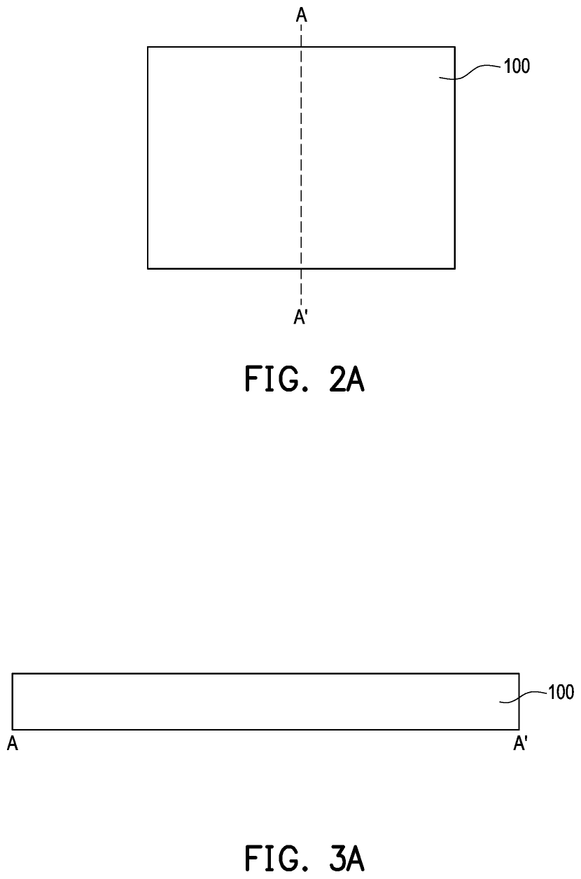

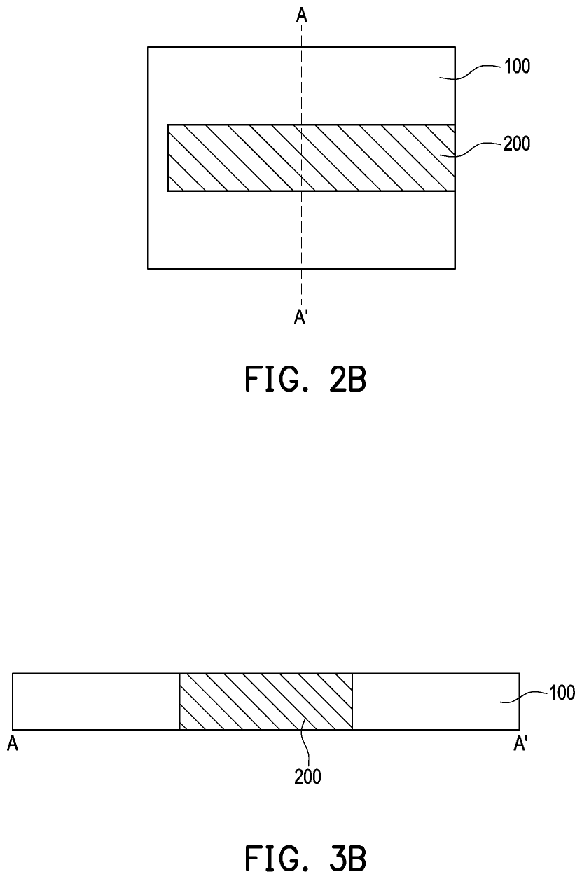

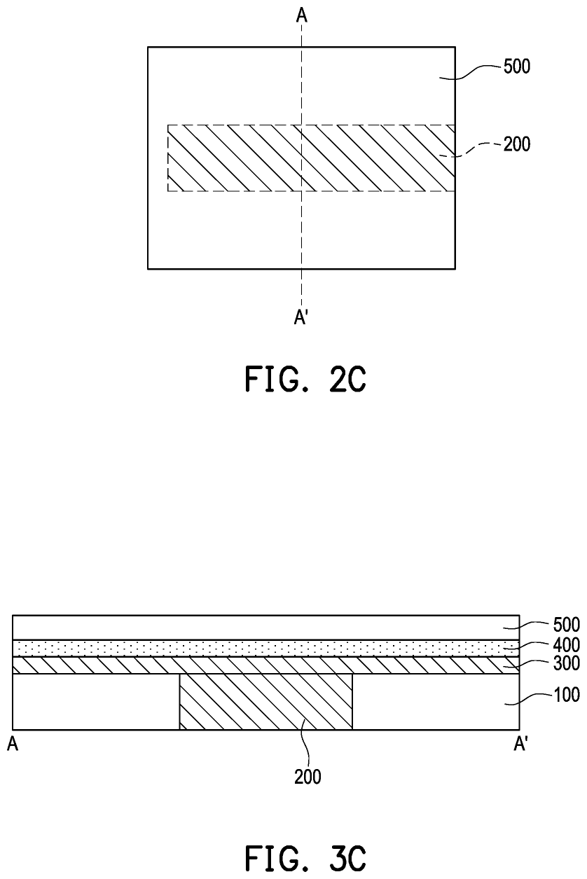

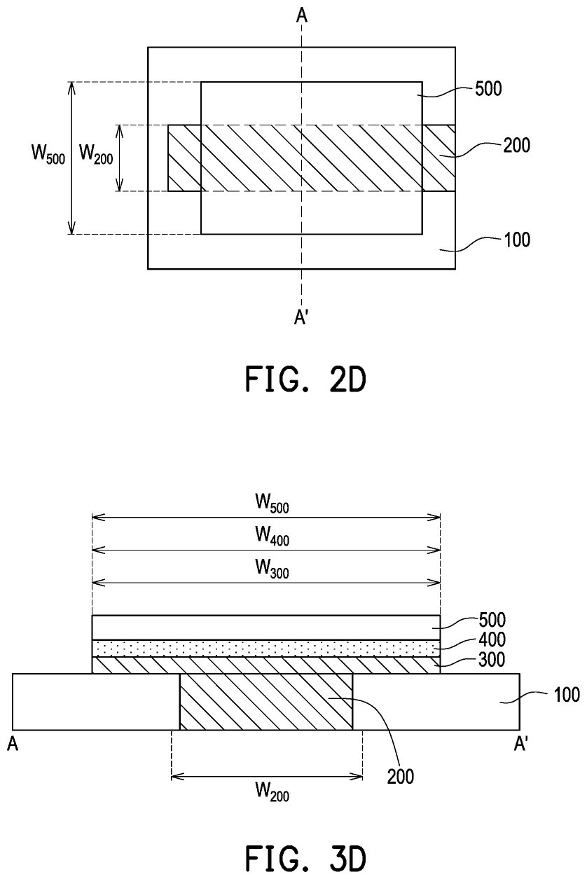

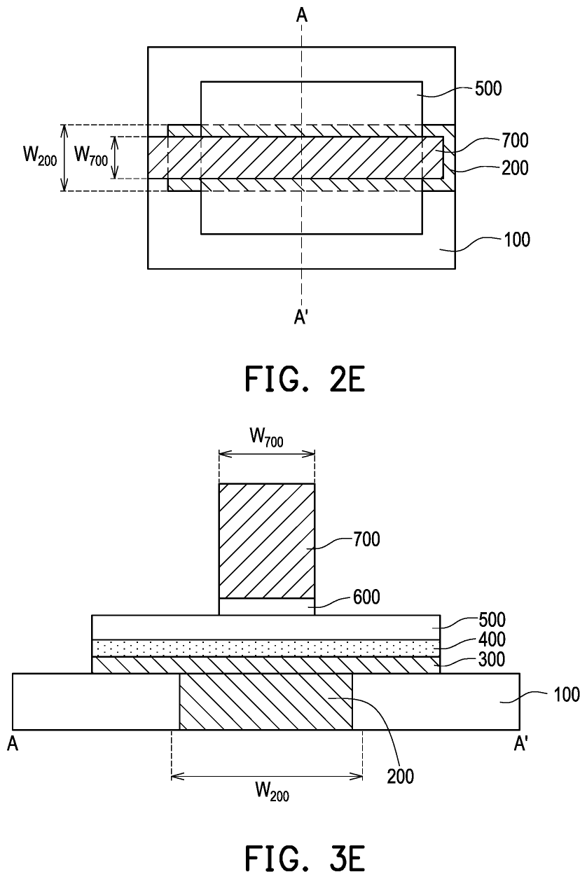

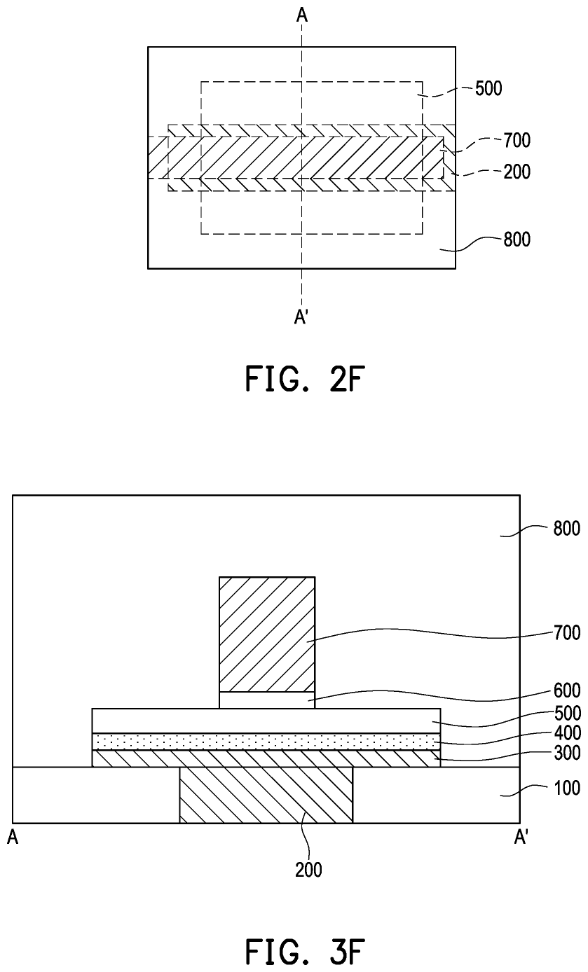

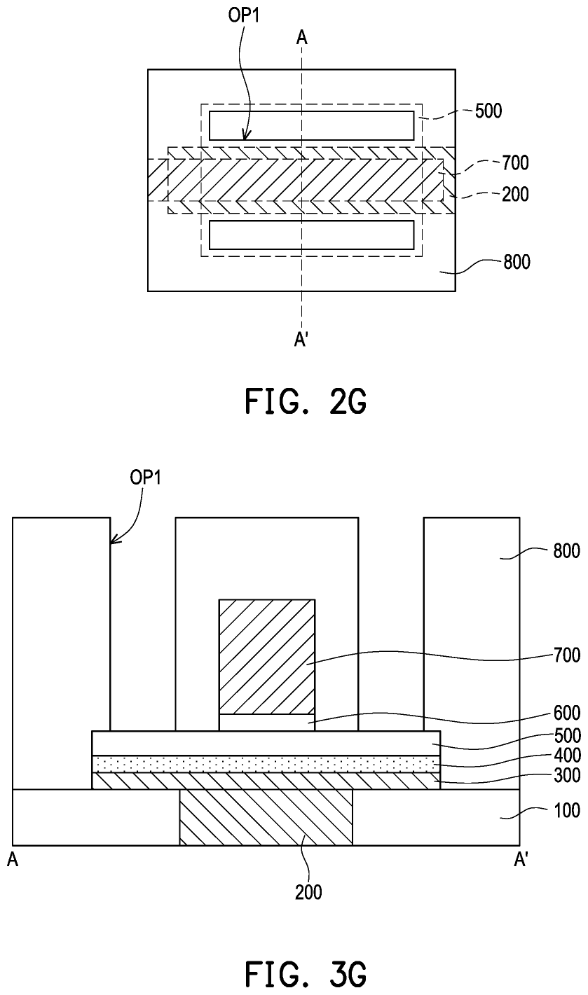

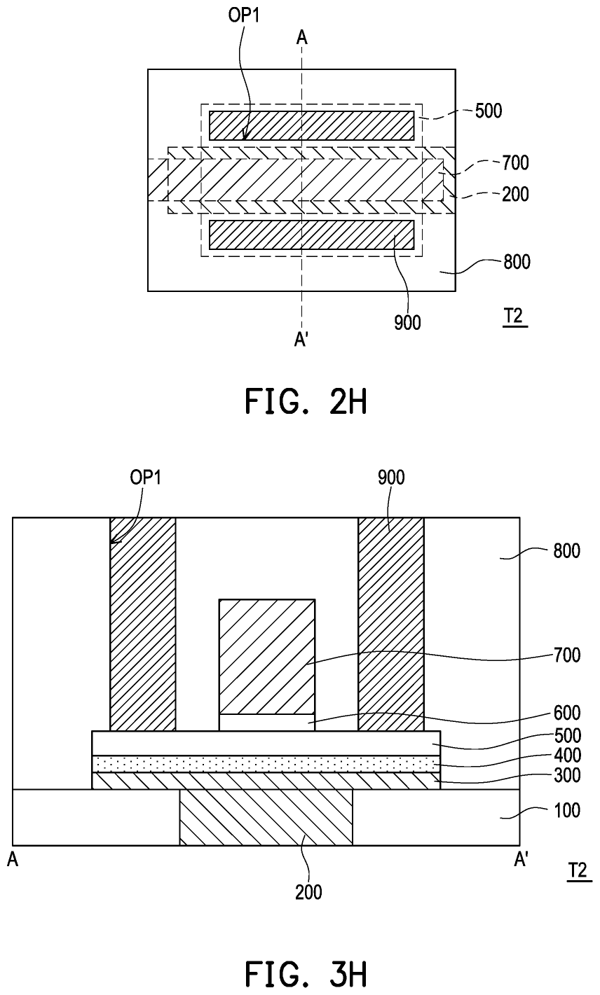

As mentioned above, the second transistors T2 are embedded in the interconnect structure 30. Taking the topmost second transistor T2 shown in FIG. 1 as an example, the formation method and the structure of this second transistor T2 will be described below in conjunction with FIG. 2A to FIG. 2H and FIG. 3A to FIG. 3H.

FIG. 2A to FIG. 2H are top views illustrating various stages of a manufacturing method of the second transistor T2 in FIG. 1. FIG. 3A to FIG. 3H are cross-sectional views illustrating various stages of the manufacturing method of the second transistor T2 in FIG. 2A to FIG. 2H. It should be noted that the cross-sectional views of FIG. 3A to FIG. 3H are taken along cross-sectional line A-A′ in FIG. 2A to FIG. 2H.

Referring to FIG. 2A and FIG. 3A, a first dielectric layer 100 is provided. In some embodiments, the first dielectric layer 100 is one of the dielectric layers 36 of the interconnect structure 30 of FIG. 1, so the detailed description thereof is omitted herein.

Referring to FIG. 2B and FIG. 3B, a gate electrode 200 is formed in the first dielectric layer 100. The gate electrode 200 may be formed by suitable fabrication techniques, such as a damascene gate formation process. In some embodiments, the first dielectric layer 100 is first patterned to form a trench therein. The first dielectric layer 100 may be patterned through a photolithography and etching process. The etching process includes, for example, an anisotropic etching process such as dry etch or an isotropic etching process such as wet etch. In some embodiments, an etchant for the wet etch includes a combination of hydrogen fluoride (HF) and ammonia (NH₃), a combination of HF and tetramethylammonium hydroxide (TMAH), or the like. On the other hand, the dry etch process includes, for example, reactive ion etch (RIE), inductively coupled plasma (ICP) etch, electron cyclotron resonance (ECR) etch, neutral beam etch (NBE), and/or the like. Subsequently, a metallic material (not shown) is formed over the first dielectric layer 100 and in the trench of the first dielectric layer 100. In some embodiments, the metallic material is deposited through atomic layer deposition (ALD), CVD, physical vapor deposition (PVD), or the like. Thereafter, a polishing process is performed on the metallic material until the first dielectric layer 100 is exposed, so as to form the gate electrode 200 that is embedded in first dielectric layer 100. The polishing process includes, for example, a mechanical grinding process, a chemical mechanical polishing (CMP) process, or the like.

In some embodiments, the metallic material of the gate electrode 200 includes copper, titanium, tantalum, tungsten, aluminum, zirconium, hafnium, cobalt, titanium aluminum, tantalum aluminum, tungsten aluminum, zirconium aluminum, hafnium aluminum, any other suitable metal-containing material, or a combination thereof. In some embodiments, the gate electrode 200 also includes materials to fine-tune the corresponding work function. For example, the metallic material of the gate electrode 200 may include p-type work function materials such as Ru, Mo, WN, ZrSi₂, MoSi₂, TaSi₂, NiSi₂, or combinations thereof, or n-type work function materials such as Ag, TaCN, Mn, or combinations thereof.

In some embodiments, a barrier layer (not shown) may be optionally formed between the gate electrode 200 and the first dielectric layer 100, so as to avoid diffusion of atoms between elements. In some embodiments, materials of the barrier layer include titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), or a combination thereof.

As illustrated in FIG. 3B, the gate electrode 200 is formed such that the first dielectric layer 100 laterally surrounds the gate electrode 200. In some embodiments, a top surface of the gate electrode 200 is substantially coplanar with a top surface of the first dielectric layer 100. In some embodiments, the gate electrode 200 corresponds to one of the conductive patterns 34 in the interconnect structure 30 of FIG. 1.

Referring to FIG. 2C and FIG. 3C, a metal layer 300, a ferroelectric layer 400, and a channel layer 500 are sequentially deposited on the first dielectric layer 100 and the gate electrode 200. In some embodiments, the metal layer 300 is in physical contact with the first dielectric layer 100 and the gate electrode 200. For example, a portion of the metal layer 300 is sandwiched between the first dielectric layer 100 and the ferroelectric layer 400. Meanwhile, another portion of the metal layer 300 is sandwiched between the gate electrode 200 and the ferroelectric layer 400. In some embodiments, a material of the metal layer 300 includes TiN, TaN, TiAl, or a combination thereof. In some embodiments, the metal layer 300 is deposited through CVD, ALD, plating, or other suitable deposition techniques. In some embodiments, the metal layer 300 that is introduced between the gate electrode 200 and the ferroelectric layer 400 is able to enhance the performance of the subsequently formed second transistor T2. In some embodiments, the metal layer 300 is optional.

As illustrated in FIG. 3C, the ferroelectric layer 400 is disposed over the first dielectric layer 100 and the gate electrode 200. For example, the ferroelectric layer 400 is disposed on the metal layer 300 and is sandwiched between the metal layer 300 and the channel layer 500. In some embodiments, a material of the ferroelectric layer 400 includes HfO₂, HfZrO, AlScN, GaScN, or the like. In some embodiments, the ferroelectric layer 400 further includes dopants. The dopants include, for example, Si, Sc, Al, In, or the like. In some embodiments, a thickness of the ferroelectric layer 400 ranges from about 0.5 nm to about 20 nm. In some embodiments, the ferroelectric layer 400 is formed through a plasma deposition process such as PVD, PECVD, or the like. However, the disclosure is not limited thereto. In some alternative embodiments, the ferroelectric layer 400 may be formed through a non-plasma deposition process. The non-plasma deposition process denotes a deposition process which does not involve the introduction of plasma. The non-plasma deposition process includes, for example, ALD, CVD, or the like. In some embodiments, the ferroelectric layer 400 is deposited at a temperature ranging from about 200° C. to about 400° C. In some embodiments, the ferroelectric layer 400 may serve as a gate dielectric layer for the gate electrode 200.

In some embodiments, the channel layer 500 is formed on the ferroelectric layer 400. For example, the channel layer 500 is in physical contact with the ferroelectric layer 400. In some embodiments, a material of the channel layer 500 includes IGZO, ITO, IWO, IAZO, MgZnAlO, Ga₂O₃, or the like. In some embodiments, these materials would render the channel layer 500 being unipolar. In some embodiments, the channel layer 500 is made of a single layer having one of the foregoing materials. However, the disclosure is not limited thereto. In some alternative embodiments, the channel layer 500 may be made of a laminate structure of at least two of the foregoing materials. In some embodiments, the channel layer 500 is doped with a dopant to achieve extra stability. In some embodiments, the channel layer 500 is deposited by suitable techniques, such as CVD, ALD, PVD, PECVD, epitaxial growth, or the like. In some embodiments, an optional annealing process for crystalline growth may be performed after the material for forming the channel layer 500 is deposited. In some embodiments, a temperature for the annealing process ranges from about 300° C. to about 600° C. Meanwhile, a duration of the annealing process ranges from about 1 minute to about 24 hours. In some embodiments, a thickness of the channel layer 500 ranges from about 0.5 nm to about 20 nm.

Referring to FIG. 2C to FIG. 2D and FIG. 3C to FIG. 3D, the channel layer 500, the ferroelectric layer 400, and the metal layer 300 are partially removed to expose a portion of the first dielectric layer 100. In some embodiments, the channel layer 500, the ferroelectric layer 400, and the metal layer 300 are partially removed through a lithography process and an etching process. The lithography process includes, for example, photoresist coating, soft baking, exposing, post-exposure baking (PEB), developing, and hard baking. The etching process includes, for example, an isotropic etching process and/or an anisotropic etching process. For example, the channel layer 500, the ferroelectric layer 400, and the metal layer 300 may be partially removed through a wet etching process, a drying etching process, or a combination thereof.

As illustrated in FIG. 2D and FIG. 3D, a width W₅₀₀ of the remaining channel layer 500, a width W₄₀₀ of the remaining ferroelectric layer 400, and a width W₃₀₀ of the remaining metal layer 300 are substantially equal to one another. For example, sidewalls of the channel layer 500, sidewalls of the ferroelectric layer 400, and sidewalls of the metal layer 300 are aligned. Meanwhile, the width W₅₀₀ of the channel layer 500, the width W₄₀₀ of the ferroelectric layer 400, and the width W₃₀₀ of the metal layer 300 are larger than a width W₂₀₀ of the gate electrode 200.

Referring to FIG. 2E and FIG. 3E, a hole supply layer 600 and a gate electrode 700 are sequentially deposited on the channel layer 500. For example, the hole supply layer 600 and the gate electrode 700 are formed on the channel layer 500 such that the hole supply layer 600 is located between the channel layer 500 and the gate electrode 700. In some embodiments, the hole supply layer 600 is in physical contact with the channel layer 500.

In some embodiments, the hole supply layer 600 is made of a dielectric material. For example, the hole supply layer 600 may be made of HfO₂, TiO₂, Al₂O₃, Si₃N₄, Ta₂O₅, or the like. In some embodiments, these materials may be amorphous or polycrystalline. In some embodiments, the hole supply layer 600 may serve as a gate dielectric layer for the gate electrode 700. However, unlike the conventional gate dielectric layer which provides low gate leakage, the hole supply layer 600 purposely provides high off-state gate leakage. In some embodiments, the leakage can be provided by trapping electrons. For example, the electron trapping promotes the trap-assisted tunneling and hence enhances the leakage. As such, the hole supply layer 600 may have high electron trapping level to provide high leakage. In some embodiments, trapping of electrons in the hole supply layer 600 means that holes are supplied to the channel layer 500 from the hole supply layer 600. That is, the hole supply layer 600 may have a high electron trapping level to provide holes to the channel layer 500. For example, an electron trap density of the hole supply layer 600 is higher than an electron trap density of the channel layer 500. Throughout the entire disclosure, electron trap density refers to the number of trapped electrons per dielectric volume. In some embodiments, the electron trap density of the hole supply layer 600 ranges from about 5e-19 cm⁻³ to about 5e-21 cm⁻³. Meanwhile, the electron trap density of the channel layer 500 ranges from about 1e-17 cm⁻³ to about 1e-19 cm⁻³. In some embodiments, the hole supply layer 600 has a low tunnel mass and a high tunnel current. In some embodiments, a bandgap of the hole supply layer 600 ranges from about 4 eV to about 6 eV. The low bandgap of the hole supply layer 600 reduces the energy barrier for holes, so as to allow hole current from the gate electrode 700 to tunnel through the hole supply layer 600 to arrive the channel layer 500. In some embodiments, a dielectric constant (k-value) of the hole supply layer 600 ranges from about 4 to about 50. In some embodiments, the hole supply layer 600 may be referred to as a “leaky gate dielectric layer.” In some embodiments, the hole supply layer 600 is formed by a lithography process and an etching process. The lithography process includes, for example, photoresist coating, soft baking, exposing, PEB, developing, and hard baking. The etching process includes, for example, an isotropic etching process and/or an anisotropic etching process. In some embodiments, the hole supply layer 600 is deposited by suitable deposition techniques such as ALD, CVD, metalorganic CVD (MOCVD), PVD, thermal oxidation, UV-ozone oxidation, remote plasma atomic layer deposition (RPALD), plasma-enhanced atomic layer deposition (PEALD), molecular beam deposition (MBD), or combinations thereof.

In some embodiments, the gate electrode 700 is disposed over the channel layer 500 and the hole supply layer 600. In some embodiments, a material of the gate electrode 700 is the same as the material of the gate electrode 200. However, the disclosure is not limited thereto. In some alternative embodiments, the material of the gate electrode 700 may be different from the material of the gate electrode 200. In some embodiments, the material of the gate electrode 700 includes copper, titanium, tantalum, tungsten, aluminum, zirconium, hafnium, cobalt, titanium aluminum, tantalum aluminum, tungsten aluminum, zirconium aluminum, hafnium aluminum, any other suitable metal-containing material, or a combination thereof. In some embodiments, the gate electrode 700 also includes materials to fine-tune the corresponding work function. For example, the metallic material of the gate electrode 700 may include p-type work function materials such as Ru, Mo, WN, ZrSi₂, MoSi₂, TaSi₂, NiSi₂, or combinations thereof, or n-type work function materials such as Ag, TaCN, Mn, or combinations thereof. In some embodiments, the gate electrode 700 further includes a barrier layer (not shown) to avoid diffusion of atoms between elements. In some embodiments, materials of the barrier layer include TiN, TaN, TiSiN, TaSiN, WSiN, TiC, TaC, TiAlC, TaAlC, TiAlN, TaAlN, or a combination thereof. In some embodiments, the gate electrode 700 is formed by a lithography process and an etching process. The lithography process includes, for example, photoresist coating, soft baking, exposing, PEB, developing, and hard baking. The etching process includes, for example, an isotropic etching process and/or an anisotropic etching process. In some embodiments, the gate electrode 700 is deposited through ALD, CVD, PVD, or the like.

As illustrated in FIG. 2E and FIG. 3E, the width W₂₀₀ of the gate electrode 200 is larger than a width W₇₀₀ of the gate electrode 700. However, the disclosure is not limited thereto. In some alternative embodiments, the width W₂₀₀ of the gate electrode 200 may be equal to the width W₇₀₀ of the gate electrode 700, or the width W₂₀₀ of the gate electrode 200 may be smaller than the width W₇₀₀ of the gate electrode 700. In the cross-sectional view of FIG. 3E, the gate electrode 700 is completely located within a span of the gate electrode 200.

As illustrated in FIG. 3E, the gate electrode 200, the metal layer 300, the ferroelectric layer 400, the channel layer 500, the hole supply layer 600, and the gate electrode 700 are vertically overlapped with one another. In some embodiments, the overlapping of these elements allows the formation of a memory cell in the subsequently formed second transistor T2. That is, a memory cell is integrated within the second transistor T2. The configurations of this memory cell will be described below.

In some embodiments, the gate electrode 200, the metal layer 300, the ferroelectric layer 400, the channel layer 500, the hole supply layer 600, and the gate electrode 700 collectively form a memory cell. In some embodiments, due to its material characteristics, the ferroelectric layer 400 may be utilized to store data. For example, the polarization state of the ferroelectric layer 400 may be altered between an up state (P-up state) and a down state (P-down state), and these states would change the threshold voltage of the second transistor T2. Therefore, by sensing the current of the second transistor T2 at a certain read voltage, the states can be distinguished, and the stored information (for example, 0 and 1) may be read. As such, the ferroelectric layer 400 may be referred to as a “storage layer.” In some embodiments, the gate electrode 200 and/or the metal layer 300 may serve as a bottom electrode of the memory cell. Meanwhile, the gate electrode 700 may serve as a top electrode of the memory cell. On the other hand, the ferroelectric layer 400 may serve as a storage layer of the memory cell. In some embodiments, since the storage layer of the memory cell is made of ferroelectric materials, the memory cell may be considered as memory cells for a FeRAM (Ferroelectric Random Access Memory).

As mentioned above, the channel layer 500 is unipolar, so the channel layer 500 lacks of holes. As such, when a negative voltage is applied to the gate electrode 700, the bands of the channel layer 500 remains flat, and the electric field in the ferroelectric layer 400 is small. As a result, the up state of the polarization state of the ferroelectric layer 400 cannot be obtained. That is, the P-up state cannot be written in the ferroelectric layer 400, and the erase operation of the memory cell cannot be performed. Nevertheless, as mentioned above, the hole supply layer 600 is able to supply holes to the channel layer 500. As such, with the presence of the hole supply layer 600 and the gate electrode 700, holes can be supplied to the channel layer 500 to resolve the foregoing issue. In other words, with the aids of the hole supply layer 600 and the gate electrode 700, the P-up state can be written and the erase operation of the memory cell can be easily performed. Therefore, the performance of the memory cell and the subsequently formed second transistor T2 may be enhanced.

Referring to FIG. 2F and FIG. 3F, a second dielectric layer 800 is formed on the first dielectric layer 100 to encapsulate the metal layer 300, the ferroelectric layer 400, the channel layer 500, the hole supply layer 600, and the gate electrode 700. In other words, the metal layer 300, the ferroelectric layer 400, the channel layer 500, the hole supply layer 600, and the gate electrode 700 are embedded in the second dielectric layer 800. As mentioned above, the first dielectric layer 100 is one of dielectric layers 36 of the interconnect structure 30 of FIG. 1. Similarly, the second dielectric layer 800 is another one of the dielectric layers 36 of the interconnect structure 30 of FIG. 1, so the detailed description thereof is omitted herein. In some embodiments, the material of the first dielectric layer 100 and the material of the second dielectric layer 800 are identical. However, the disclosure is not limited thereto. In some alternative embodiments, the material of the first dielectric layer 100 may be different from the material of the second dielectric layer 800. As illustrated in FIG. 3F, the second dielectric layer 800 is stacked on the first dielectric layer 100.

Referring to FIG. 2G and FIG. 3G, a plurality of openings OP1 is formed in the second dielectric layer 800. For example, the openings OP1 penetrate through the second dielectric layer 800 to expose at least a portion of the channel layer 500. In some embodiments, the openings OP1 are formed through a photolithography and etching process. The etching process includes, for example, an anisotropic etching process such as dry etch or an isotropic etching process such as wet etch.

Referring to FIG. 2H and FIG. 3H, source/drain contacts 900 are formed in the openings OP1 of the second dielectric layer 800. In some embodiments, the source/drain contacts 900 are formed by the following steps. First, a metallic material is formed on the second dielectric layer 800 and is filled into the openings OP1. In some embodiments, the metallic material includes cobalt, tungsten, copper, titanium, tantalum, aluminum, zirconium, hafnium, a combination thereof, or other suitable metallic materials. In some embodiments, the metallic material is formed through CVD, ALD, plating, or other suitable deposition techniques. Thereafter, a portion of the metallic material is removed through a polishing process until the second dielectric layer 800 is exposed, so as to form the source/drain contacts 900 on the channel layer 500. In some embodiments, the polishing process includes, for example, a mechanical grinding process, a CMP process, or the like.

As illustrated in FIG. 3H, the source/drain contacts 900 penetrate through the second dielectric layer 800 to be in physical contact with the channel layer 500. In some embodiments, the source/drain contacts 900 are disposed aside the gate electrode 700 and the hole supply layer 600. For example, the source/drain contacts 900 are disposed near two ends of the channel layer 500. As illustrated in FIG. 2H and FIG. 3H, the source/drain contacts are located outside of a span of the gate electrode 200. In some embodiments, the source/drain contacts 900 may serve as the source and the drain of the second transistor T2. However, the disclosure is not limited thereto. In some alternative embodiments, source/drain patterns may be formed between the channel layer 500 and the source/drain contacts 900. Under this scenario, the source/drain patterns serve as the source and the drain of the second transistor T2, and the source/drain contacts 900 serve as contact plugs for transmitting signal between the source/drain patterns and other components.

After the source/drain contacts 900 are formed, the formation of the second transistor T2 is substantially completed. Referring to FIG. 1 and FIG. 3H, some of the conductive vias 32 shown in FIG. 1 may serve as the source/drain contacts 900 to electrically connect the second transistor T2 with the conductive patterns 34. That is, the source/drain contacts 900 may be some of the conductive vias 32 in FIG. 1. In some embodiments, the second transistor T2 is electrically connected to the first transistor T1 and/or the conductive terminals 80 through the conductive vias 32 and the conductive patterns 34 of the interconnect structure 30.

In some embodiments, since the second transistor T2 includes the ferroelectric layer 400, the second transistor T2 may be referred to as a FeFET (Ferroelectric Field-Effect Transistor). As mentioned above, the second transistor T2 is embedded in the interconnect structure 30, which is being considered as formed during back-end-of-line (BEOL) process. As such, the second transistor T2 is being considered as formed during BEOL process. In some embodiments, the second transistor T2 may be referred to as a double gate transistor or a dual gate transistor.

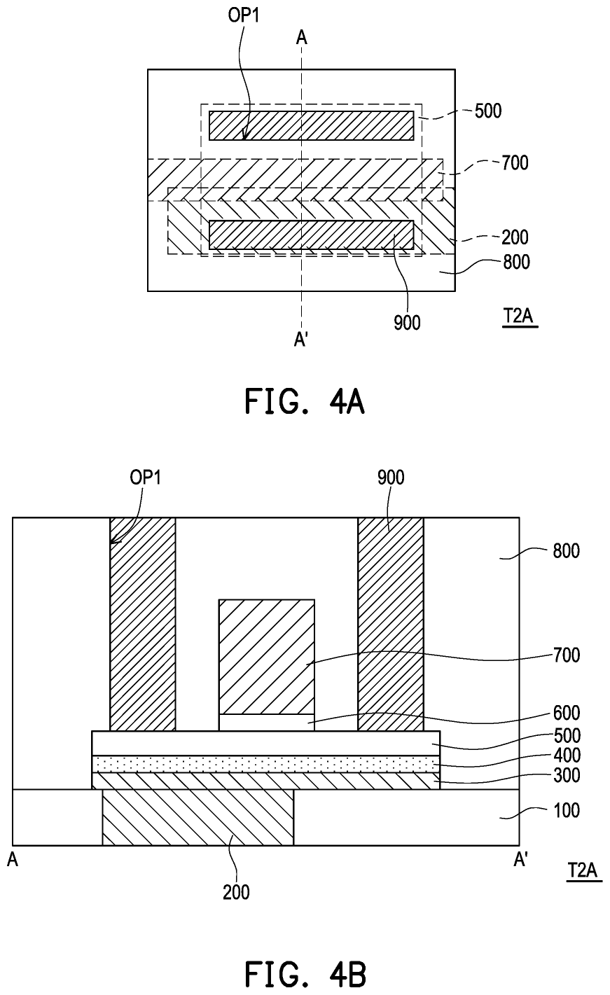

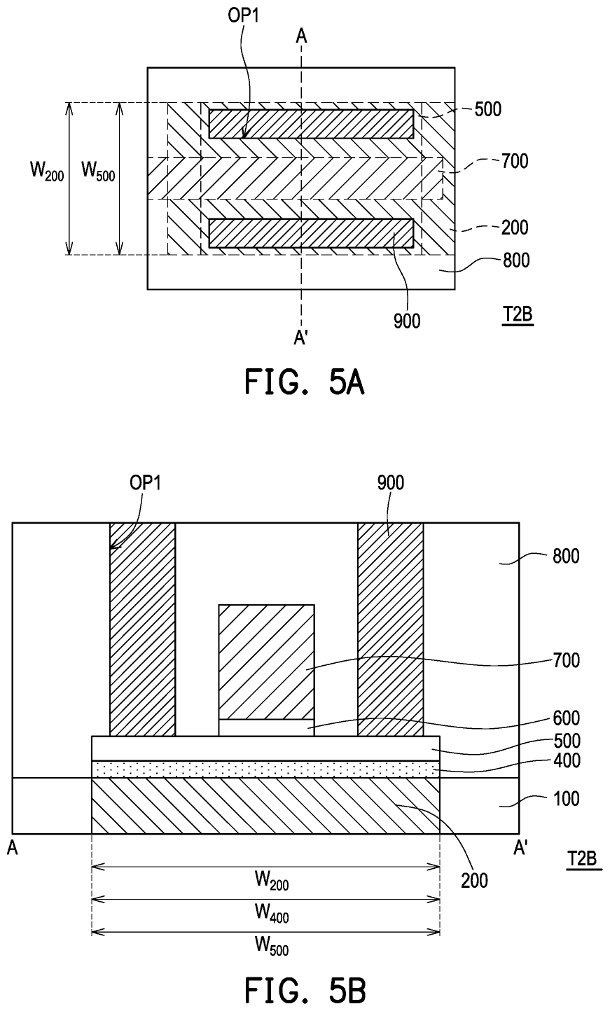

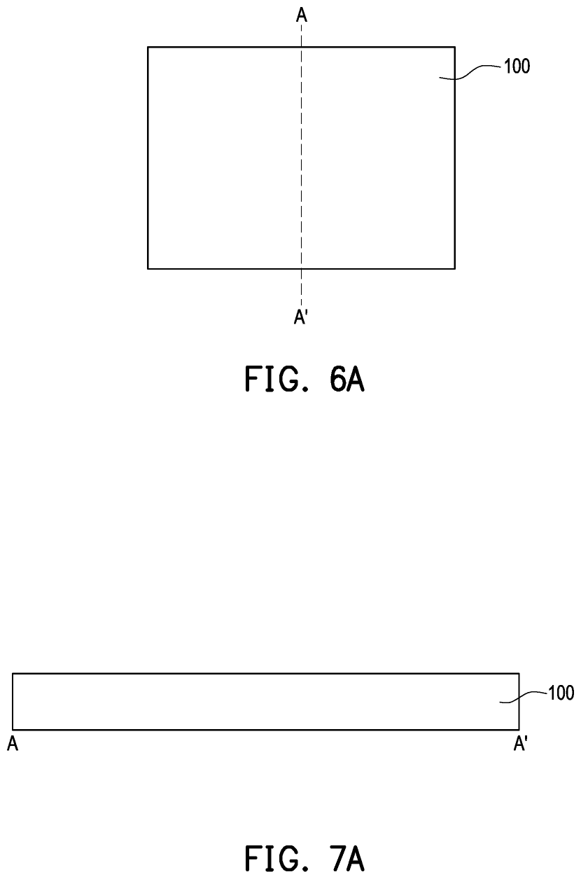

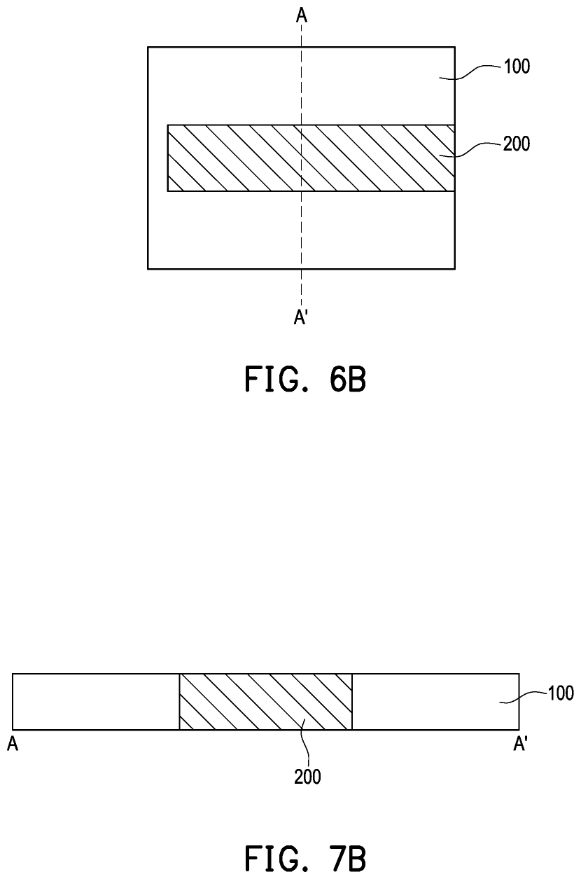

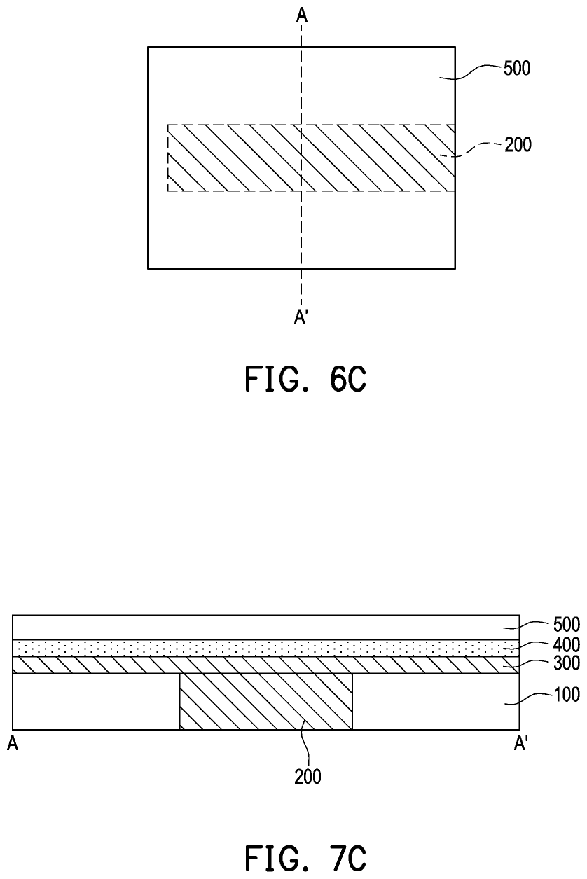

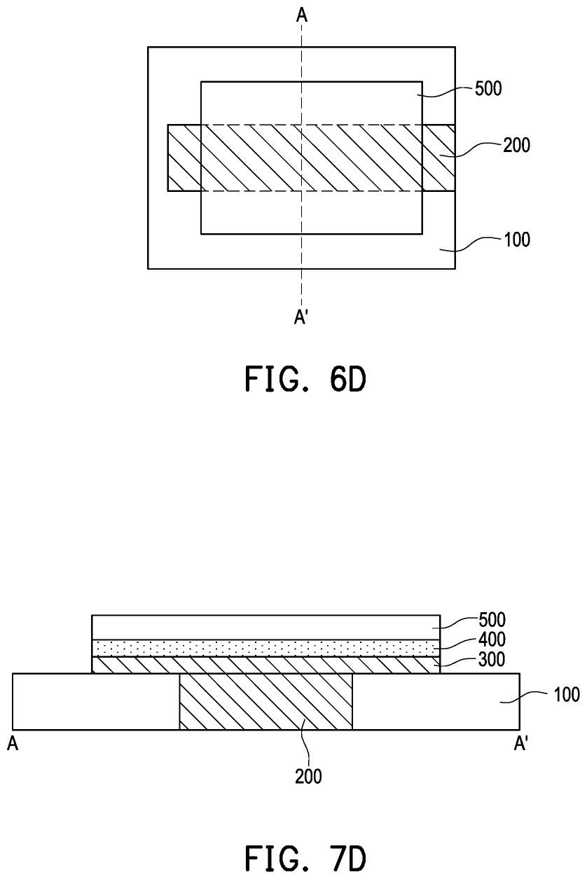

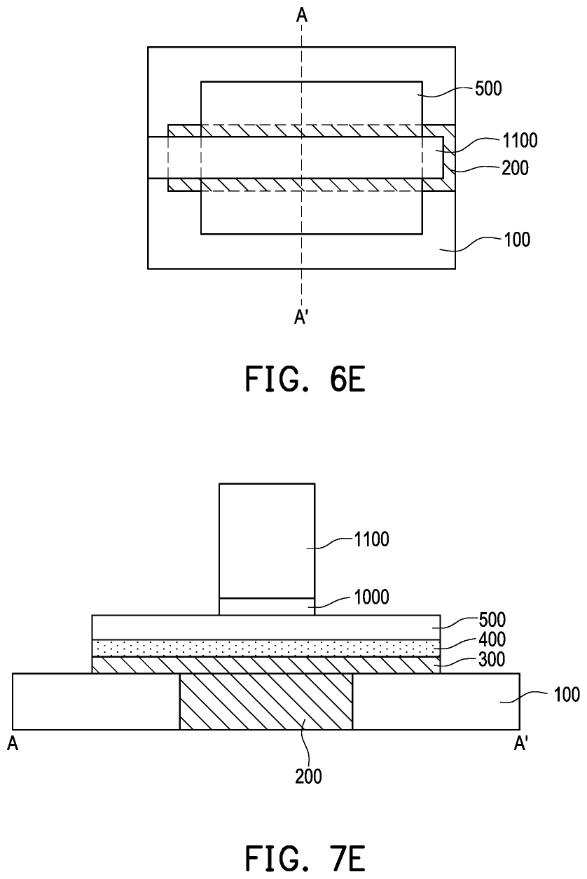

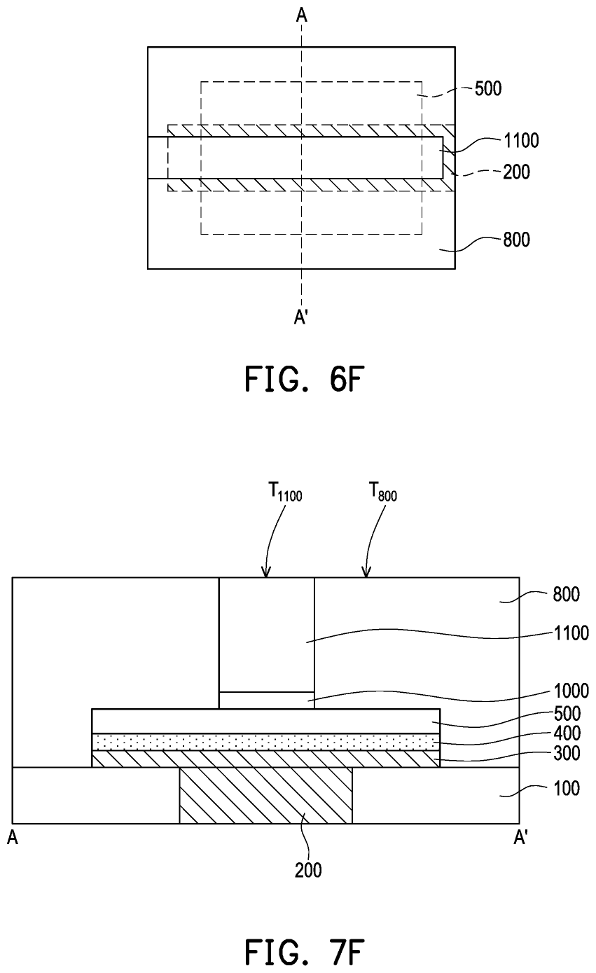

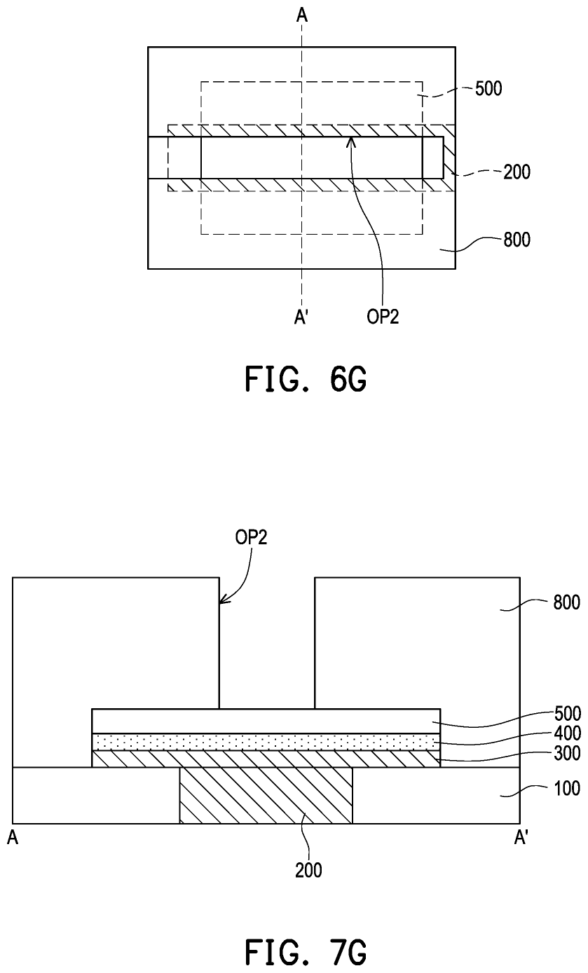

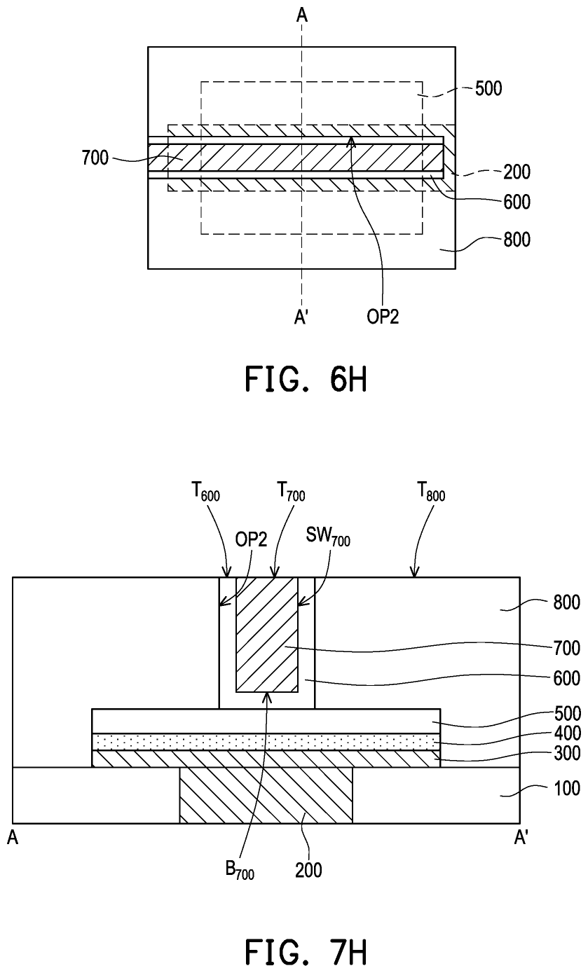

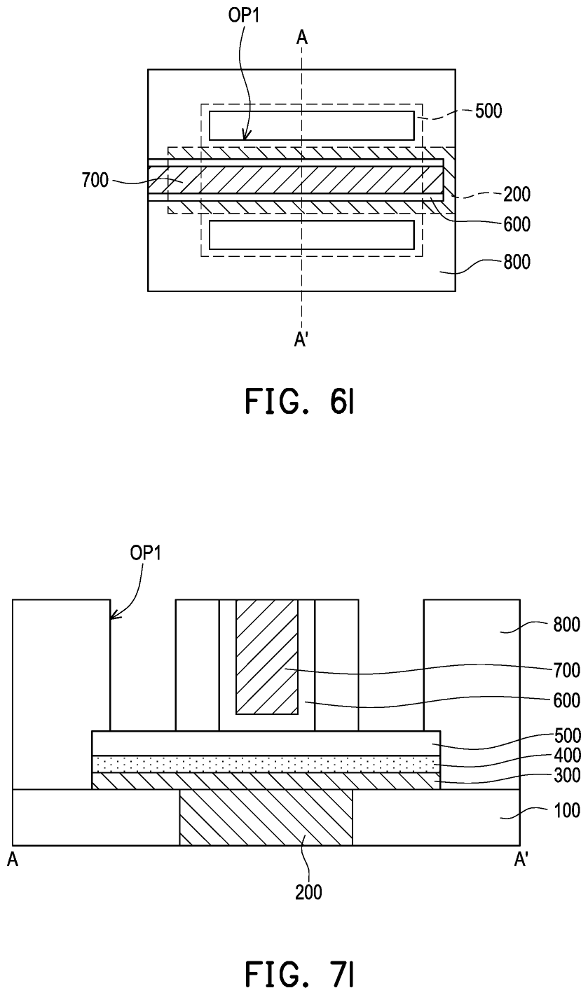

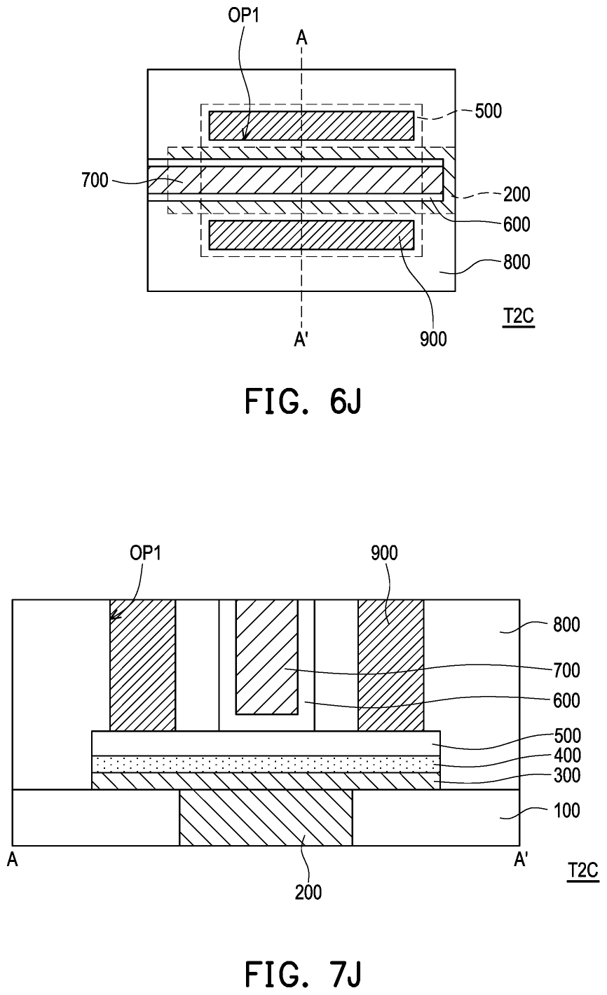

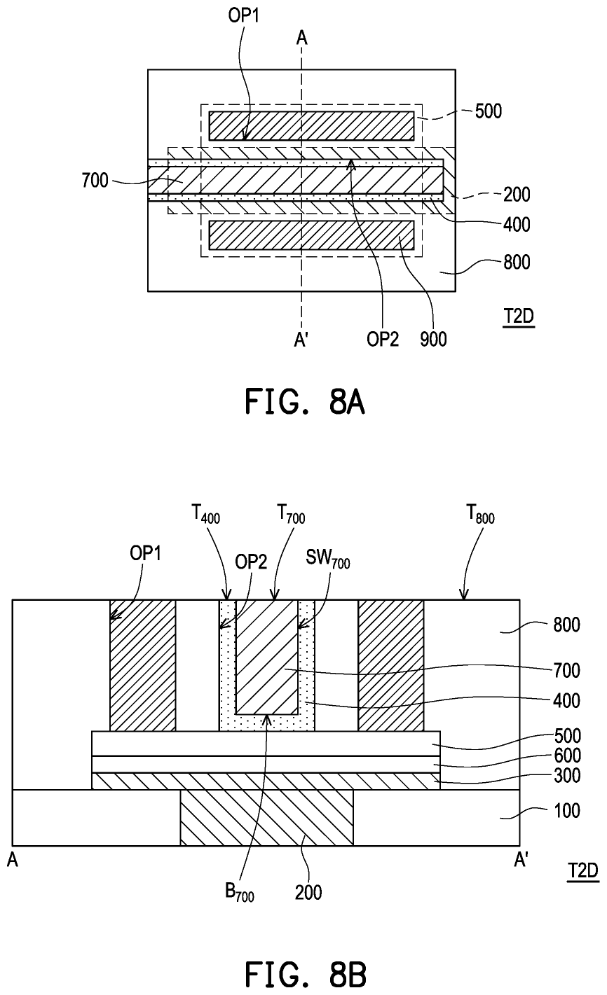

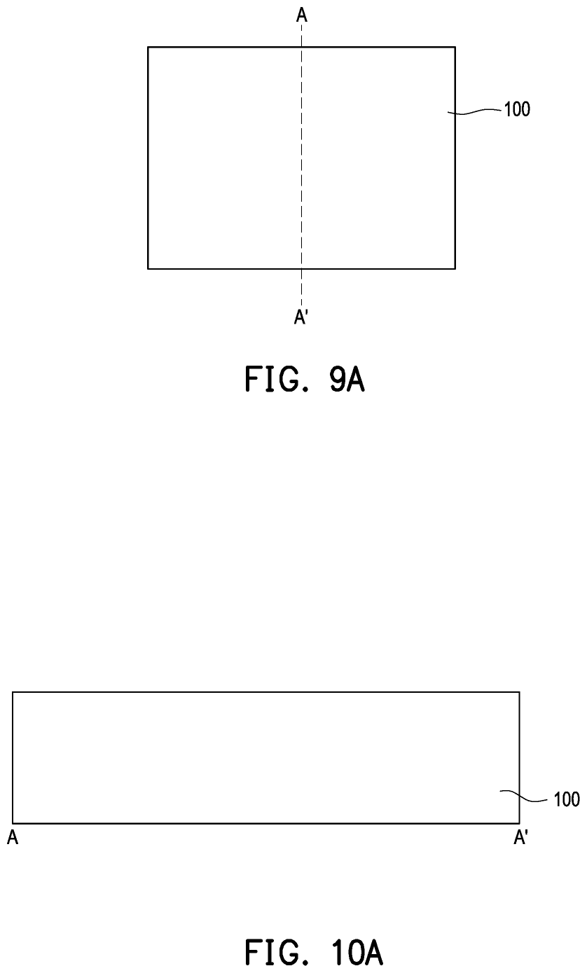

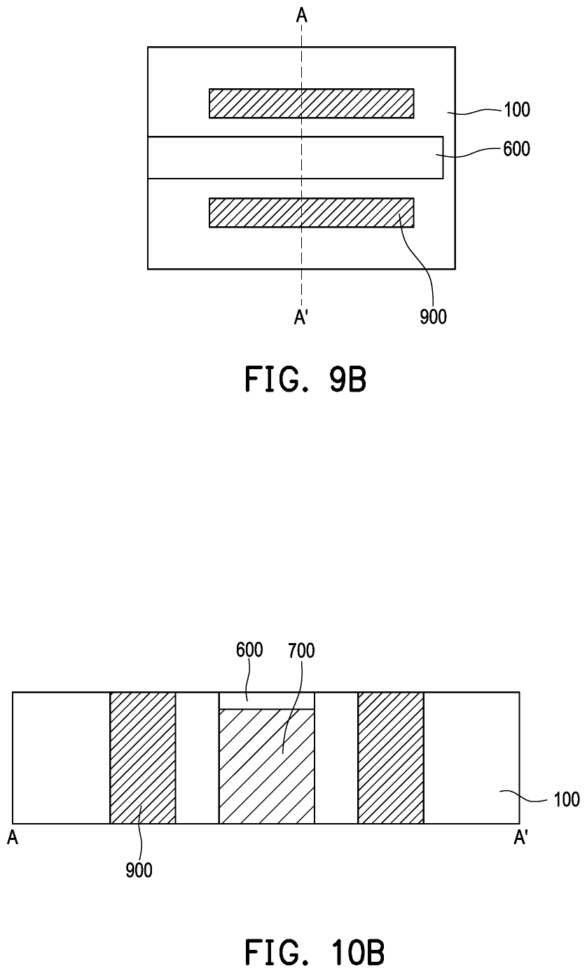

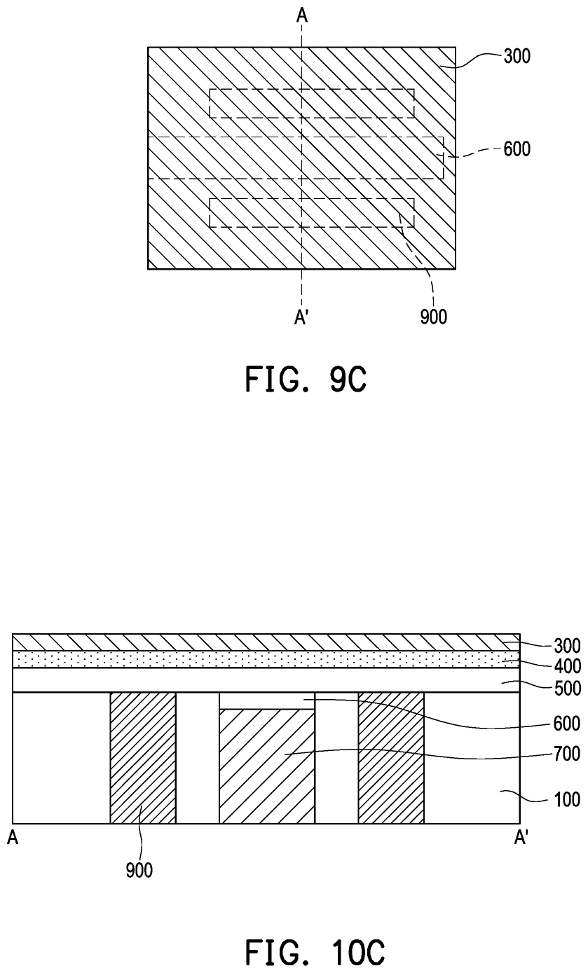

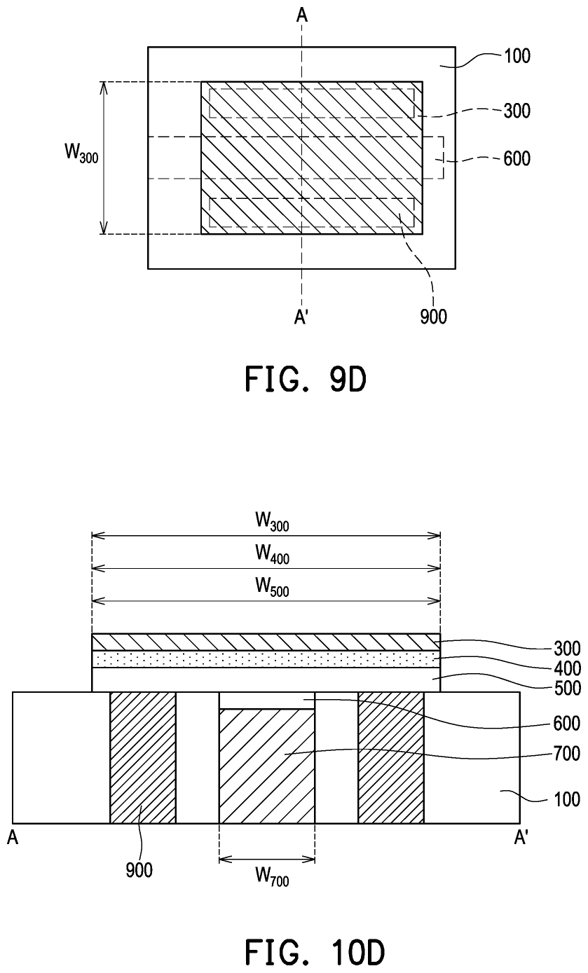

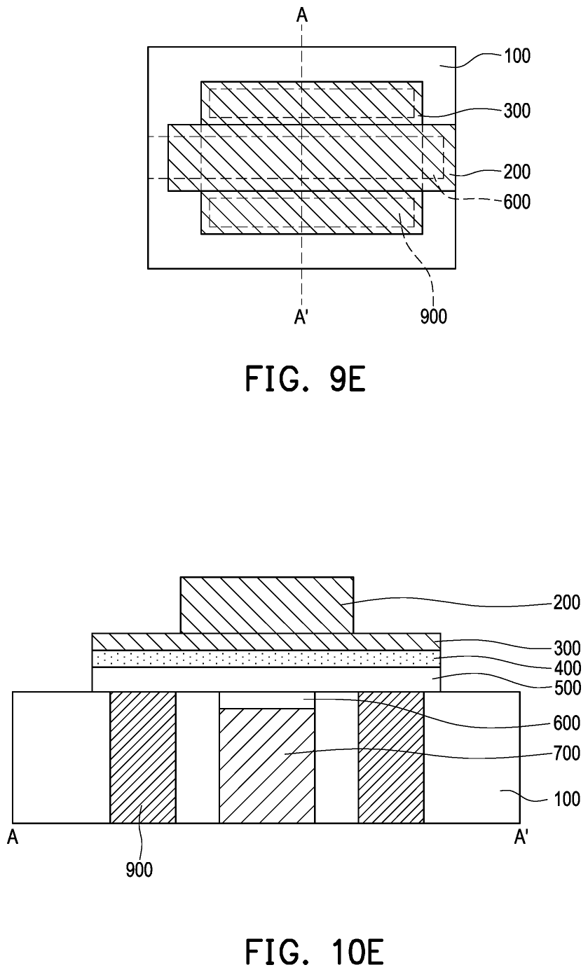

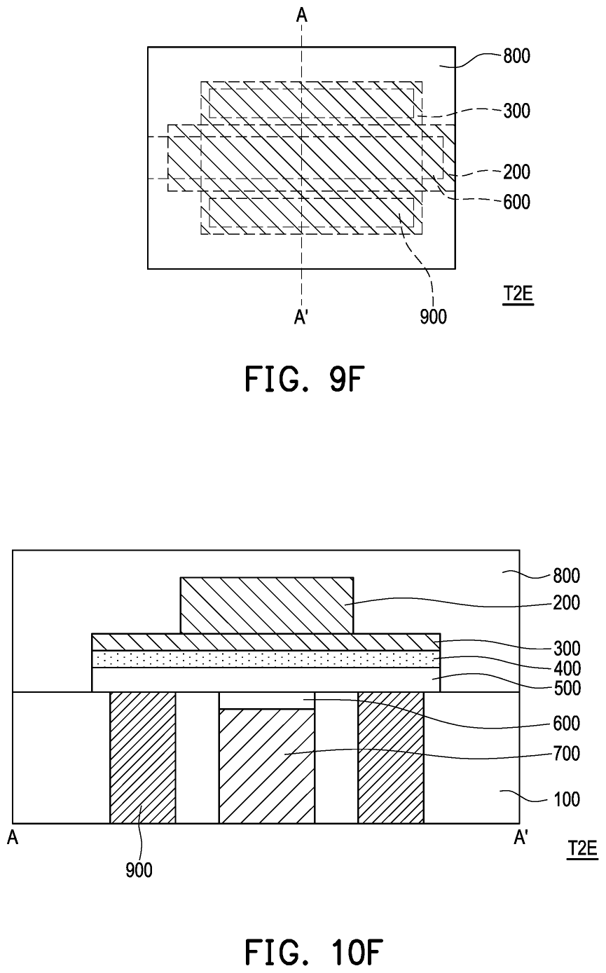

In some embodiments, the second transistor T2 illustrated in FIG. 2H and FIG. 3H is one of the examples of the second transistors T2 in FIG. 1. In some alternative embodiments, the second transistors T2 in FIG. 1 may be replaced by other transistors, such as a second transistor T2A shown in FIG. 4A and FIG. 4B, a second transistor T2B shown in FIG. 5A and FIG. 5B, a second transistor T2C shown in FIG. 6J and FIG. 7J, a second transistor T2D shown in FIG. 8A and FIG. 8B, or a second transistor T2E shown in FIG. 9F and FIG. 10F.

FIG. 4A is a top view of a second transistor T2A in accordance with some alternative embodiments of the disclosure. FIG. 4B is a cross-sectional view of the second transistor T2A in FIG. 4A. It should be noted that the cross-sectional view of FIG. 4B is taken along cross-sectional line A-A′ in FIG. 4A.

Referring to FIG. 4A and FIG. 4B, the second transistor T2A in FIG. 4A and FIG. 4B is similar to the second transistor T2 in FIG. 2H and FIG. 3H, so similar elements are denoted by the same reference numeral and the detailed descriptions thereof are omitted herein. The difference between the second transistor T2A of FIG. 4A and FIG. 4B and the second transistor T2 of FIG. 2H and FIG. 3H lies in the location of the gate electrode 200. As illustrated in FIG. 4A and FIG. 4B, the gate electrode 200 and the gate electrode 700 are misaligned and have an offset. In some embodiments, the gate electrode 200 is partially overlapped with the gate electrode 700. For example, the gate electrode 700 is partially located within a span of the gate electrode 200. In other words, the gate electrode 700 extends beyond one edge of the gate electrode 200. Meanwhile, the gate electrode 700 does not extend beyond another edge of the gate electrode 200. In some embodiments, one of the source/drain contacts 900 is located within the span of the gate electrode 200. On the other hand, another one of the source/drain contacts 900 is located outside of the span of the gate electrode 200.

In some embodiments, with the aids of the hole supply layer 600 and the gate electrode 700, the P-up state can be written in the ferroelectric layer 400 and the erase operation of the memory cell can be easily performed. Therefore, the performance of the memory cell and the second transistor T2A may be enhanced.

FIG. 5A is a top view of a second transistor T2B in accordance with some alternative embodiments of the disclosure. FIG. 5B is a cross-sectional view of the second transistor T2B in FIG. 5A. It should be noted that the cross-sectional view of FIG. 5B is taken along cross-sectional line A-A′ in FIG. 5A.

Referring to FIG. 5A and FIG. 5B, the second transistor T2B in FIG. 5A and FIG. 5B is similar to the second transistor T2 in FIG. 2H and FIG. 3H, so similar elements are denoted by the same reference numeral and the detailed descriptions thereof are omitted herein. The difference between the second transistor T2B of FIG. 5A and FIG. 5B and the second transistor T2 of FIG. 2H and FIG. 3H lies in the shape of the gate electrode 200. In addition, the metal layer 300 in the second transistor T2 of FIG. 2H and FIG. 3H is omitted in the second transistor T2B of FIG. 5A and FIG. 5B. As illustrated in FIG. 5A and FIG. 5B, a width W₂₀₀ of the gate electrode 200 is substantially equal to a width W₄₀₀ of the ferroelectric layer 400 and a width W₅₀₀ of the channel layer 500. In other words, sidewalls of the gate electrode 200, sidewalls of the ferroelectric layer 400, and sidewalls of the channel layer 500 are aligned. In some embodiments, the source/drain contacts 900 are located within a span of the gate electrode 200. In some embodiments, the ferroelectric layer 400 is in physical contact with the gate electrode 200.

In some embodiments, with the aids of the hole supply layer 600 and the gate electrode 700, the P-up state can be written in the ferroelectric layer 400 and the erase operation of the memory cell can be easily performed. Therefore, the performance of the memory cell and the second transistor T2B may be enhanced.

FIG. 6A to FIG. 6J are top views illustrating various stages of a manufacturing method of the second transistor T2C in accordance with some alternative embodiments of the disclosure. FIG. 7A to FIG. 7J are cross-sectional views illustrating various stages of the manufacturing method of the second transistor T2C in FIG. 6A to FIG. 6J. It should be noted that the cross-sectional views of FIG. 7A to FIG. 7J are taken along cross-sectional line A-A′ in FIG. 6A to FIG. 6J.

Referring to FIG. 6A to FIG. 6D and FIG. 7A to FIG. 7D, the steps shown in FIG. 6A to FIG. 6D and FIG. 7A to FIG. 7D are respectively similar to the steps shown in FIG. 2A to FIG. 2D and FIG. 3A to FIG. 3D, so similar elements are denoted by the same reference numeral and the detailed descriptions thereof are omitted herein.

Referring to FIG. 6E and FIG. 7E, a dummy gate dielectric layer 1000 and a dummy gate electrode 1100 are sequentially deposited on the channel layer 500. For example, the dummy gate dielectric layer 1000 and the dummy gate electrode 1100 are formed on the channel layer 500 such that the dummy gate dielectric layer 1000 is located between the channel layer 500 and the dummy gate electrode 1100. In some embodiments, the dummy gate dielectric layer 1000 is in physical contact with the channel layer 500.

In some embodiments, the dummy gate dielectric layer 1000 includes silicon oxide, silicon nitride, silicon oxy-nitride, or high-k dielectrics. In some embodiments, high-k dielectrics include metal oxides. It should be noted that the high-k dielectric materials are generally dielectric materials having a dielectric constant greater than 4. Examples of metal oxides used for high-k dielectrics include oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or mixtures thereof. In some embodiments, the dummy gate dielectric layer 1000 is formed by a lithography process and an etching process. The lithography process includes, for example, photoresist coating, soft baking, exposing, PEB, developing, and hard baking. The etching process includes, for example, an isotropic etching process and/or an anisotropic etching process. In some embodiments, the dummy gate dielectric layer 1000 is deposited by suitable deposition techniques such as ALD, CVD, PVD, thermal oxidation, UV-ozone oxidation, or combinations thereof.

In some embodiments, the dummy gate electrode 1100 is disposed over the channel layer 500 and the dummy gate dielectric layer 1000. In some embodiments, the dummy gate electrode 1100 is a single layered structure. However, the disclosure is not limited thereto. In some alternative embodiments, the dummy gate electrode 1100 may be multi-layered structure. In some embodiment, the dummy gate electrode 1100 include a silicon-containing material, such as poly-silicon, amorphous silicon, or a combination thereof. In some embodiments, the dummy gate electrode 1100 is formed by a lithography process and an etching process. The lithography process includes, for example, photoresist coating, soft baking, exposing, PEB, developing, and hard baking. The etching process includes, for example, an isotropic etching process and/or an anisotropic etching process. In some embodiments, the dummy gate electrode 1100 is deposited through ALD, CVD, PVD, or combinations thereof.

Referring to FIG. 6F and FIG. 7F, a second dielectric layer 800 is formed on the first dielectric layer 100 to encapsulate the metal layer 300, the ferroelectric layer 400, the channel layer 500, the dummy gate dielectric layer 1000, and the dummy gate electrode 1100. In other words, the metal layer 300, the ferroelectric layer 400, the channel layer 500, the dummy gate dielectric layer 1000, and the dummy gate electrode 1100 are embedded in the second dielectric layer 800. The second dielectric layer 800 in FIG. 6F and FIG. 7F is similar to the second dielectric layer 800 in FIG. 2F and FIG. 3F, so the detailed description thereof is omitted herein. As illustrated in FIG. 7F, the second dielectric layer 800 exposes the dummy gate electrode 1100. For example, a top surface T₁₁₀₀ of the dummy gate electrode 1100 is exposed by the second dielectric layer 800. That is, the top surface T₁₁₀₀ of the dummy gate electrode 1100 and a top surface T₈₀₀ of the second dielectric layer 800 are substantially coplanar.

Referring to FIG. 6F to FIG. 6G and FIG. 7F to FIG. 7G, the dummy gate dielectric layer 1000 and the dummy gate electrode 1100 are removed to form an opening OP2 in the second dielectric layer 800. In some embodiments, the dummy gate dielectric layer 1000 and the dummy gate electrode 1100 are removed through an etching process or other suitable processes. For example, the dummy gate dielectric layer 1000 and the dummy gate electrode 1100 may be removed through wet etching or dry etching. Example of wet etching includes chemical etching and example of dry etching includes plasma etching, but the disclosure is not limited thereto. Other commonly known etching method may also be adapted to perform the removal of the dummy gate dielectric layer 1000 and the dummy gate electrode 1100. In some embodiments, the opening OP2 exposes a portion of the channel layer 500.

Referring to FIG. 6H and FIG. 7H, a hole supply layer 600 and a gate electrode 700 are deposited in the opening OP2 of the second dielectric layer 800. For example, the hole supply layer 600 and the gate electrode 700 fill up the opening OP2 of the second dielectric layer 800. That is, a top surface T₆₀₀ of the hole supply layer 600, a top surface T₇₀₀ of the gate electrode 700, and the top surface T₈₀₀ of the second dielectric layer 800 are substantially coplanar. In some embodiments, formation methods and materials of the hole supply layer 600 and the gate electrode 700 in FIG. 6H and FIG. 7H are respectively similar to that of the hole supply layer 600 and the gate electrode 700 in FIG. 2E and FIG. 3E, so the detailed descriptions thereof are omitted herein. As illustrated in FIG. 7H, the hole supply layer 600 wraps around the gate electrode 700. For example, the hole supply layer 600 covers a bottom surface B₇₀₀ and sidewalls SW₇₀₀ of the gate electrode 700. That is, a portion of the hole supply layer 600 is sandwiched between the gate electrode 700 and the channel layer 500, and another portion of the hole supply layer 600 is sandwiched between the gate electrode 700 and the second dielectric layer 800. In some embodiments, the hole supply layer 600 exhibits a U-shape from the cross-sectional view of FIG. 7H. Meanwhile, the hole supply layer 600 are two long strips sandwiching the gate electrode 700 from the top view of FIG. 6H.

In some embodiments, the steps shown in FIG. 6E to FIG. 6H and FIG. 7E to FIG. 7H are collectively referred to as a “metal gate replacement process.” That is, the dummy gate electrode 1100 including polysilicon is replaced by the gate electrode 700 which includes metal. Since the dummy gate electrode 1100 is being replaced by the gate electrode 700, subsequent processes of forming metallic interconnection (not shown) can be implemented. For instance, other conductive lines (not shown) may be formed to electrically connect the gate electrode 700 with other elements.

Referring to FIG. 6I to FIG. 6J and FIG. 7I to FIG. 7J, the steps shown in FIG. 6I to FIG. 6J and FIG. 7I to FIG. 7J are respectively similar to the steps shown in FIG. 2G to FIG. 2H and FIG. 3G to FIG. 3H, so similar elements are denoted by the same reference numeral and the detailed descriptions thereof are omitted herein. As illustrated in FIG. 7J, a second transistor T2C is obtained.

In some embodiments, with the aids of the hole supply layer 600 and the gate electrode 700, the P-up state can be written in the ferroelectric layer 400 and the erase operation of the memory cell can be easily performed. Therefore, the performance of the memory cell and the second transistor T2C may be enhanced.

FIG. 8A is a top view of a second transistor T2D in accordance with some alternative embodiments of the disclosure. FIG. 8B is a cross-sectional view of the second transistor T2D in FIG. 8A. It should be noted that the cross-sectional view of FIG. 8B is taken along cross-sectional line A-A′ in FIG. 8A.

Referring to FIG. 8A and FIG. 8B, the second transistor T2D in FIG. 8A and FIG. 8B is similar to the second transistor T2C in FIG. 6J and FIG. 7J, so similar elements are denoted by the same reference numeral and the detailed descriptions thereof are omitted herein. The difference between the second transistor T2D of FIG. 8A and FIG. 8B and the second transistor T2C of FIG. 6J and FIG. 7J lies in that the locations of the ferroelectric layer 400 and the hole supply layer 600 in the second transistor T2C of FIG. 6J and FIG. 7J are exchanged in the second transistor T2D of FIG. 8A and FIG. 8B. As illustrated in FIG. 8B, the hole supply layer 600 is sandwiched between the metal layer 300 and the channel layer 500. On the other hand, the ferroelectric layer 400 wraps around the gate electrode 700. For example, the ferroelectric layer 400 covers a bottom surface B₇₀₀ and sidewalls SW₇₀₀ of the gate electrode 700. That is, a portion of the ferroelectric layer 400 is sandwiched between the gate electrode 700 and the channel layer 500, and another portion of the ferroelectric layer 400 is sandwiched between the gate electrode 700 and the second dielectric layer 800. As illustrated in FIG. 8B, a top surface T₄₀₀ of the ferroelectric layer 400, a top surface T₇₀₀ of the gate electrode 700, and a top surface T₈₀₀ of the second dielectric layer 800 are substantially coplanar. In some embodiments, the ferroelectric layer 400 exhibits a U-shape from the cross-sectional view of FIG. 8B. Meanwhile, the ferroelectric layer 400 are two long strips sandwiching the gate electrode 700 from the top view of FIG. 8A.

In some embodiments, with the aids of the hole supply layer 600 and the gate electrode 700, the P-up state can be written in the ferroelectric layer 400 and the erase operation of the memory cell can be easily performed. Therefore, the performance of the memory cell and the second transistor T2D may be enhanced.

FIG. 9A to FIG. 9F are top views illustrating various stages of a manufacturing method of the second transistor T2E in accordance with some alternative embodiments of the disclosure. FIG. 10A to FIG. 10F are cross-sectional views illustrating various stages of the manufacturing method of the second transistor T2E in FIG. 9A to FIG. 9F. It should be noted that the cross-sectional views of FIG. 10A to FIG. 10F are taken along cross-sectional line A-A′ in FIG. 9A to FIG. 9F.

Referring to FIG. 9A and FIG. 10A, a first dielectric layer 100 is provided. In some embodiments, the first dielectric layer 100 in FIG. 9A and FIG. 10A is similar to the first dielectric layer 100 in FIG. 2A and FIG. 3A, so the detailed description thereof is omitted herein.

Referring to FIG. 9B and FIG. 10B, a hole supply layer 600, a gate electrode 700, and source/drain contacts 900 are formed in the first dielectric layer 100. For example, the hole supply layer 600, the gate electrode 700, and the source/drain contacts 900 are embedded in the first dielectric layer 100. In some embodiments, the hole supply layer 600 and the gate electrode 700 in FIG. 9B and FIG. 10B are respectively similar to the hole supply layer 600 and the gate electrode 700 in FIG. 2E and FIG. 3E, so the detailed descriptions thereof are omitted herein. As illustrated in FIG. 10B, the hole supply layer 600 is disposed on top of the gate electrode 700. In some embodiments, the source/drain contacts in FIG. 9B and FIG. 10B are similar to the source/drain contacts 900 in FIG. 2H and FIG. 3H, so the detailed descriptions thereof are omitted herein. As illustrated in FIG. 9B and FIG. 10B, the source/drain contacts 900 are disposed aside the hole supply layer 600 and the second gate electrode 700.

Referring to FIG. 9C and FIG. 10C, a channel layer 500, a ferroelectric layer 400, and a metal layer 300 are sequentially deposited on the first dielectric layer 100, the hole supply layer 600, and the source/drain contacts 900. For example, the ferroelectric layer 400 is sandwiched between the channel layer 500 and the metal layer 300. In some embodiments, the channel layer 500 is in physical contact with the first dielectric layer 100, the hole supply layer 600, and the source/drain contacts 900. In some embodiments, the channel layer 500, the ferroelectric layer 400, and the metal layer 300 in FIG. 9C and FIG. 10C are respectively similar to the channel layer 500, the ferroelectric layer 400, and the metal layer 300 in FIG. 2C and FIG. 3C, so the detailed descriptions thereof are omitted herein.

Referring to FIG. 9C to FIG. 9D and FIG. 10C to FIG. 10D, the metal layer 300, the ferroelectric layer 400, and the channel layer 500 are partially removed to expose a portion of the first dielectric layer 100. In some embodiments, the metal layer 300, the ferroelectric layer 400, and the channel layer 500 are partially removed through a lithography process and an etching process. The lithography process includes, for example, photoresist coating, soft baking, exposing, PEB, developing, and hard baking. The etching process includes, for example, an isotropic etching process and/or an anisotropic etching process. For example, the metal layer 300, the ferroelectric layer 400, and the channel layer 500 may be partially removed through a wet etching process, a drying etching process, or a combination thereof.

As illustrated in FIG. 9D and FIG. 10D, a width W₃₀₀ of the remaining metal layer 300, a width W₄₀₀ of the remaining ferroelectric layer 400, and a width W₅₀₀ of the remaining channel layer 500 are substantially equal to one another. For example, sidewalls of the metal layer 300, sidewalls of the ferroelectric layer 400, and sidewalls of the channel layer 500 are aligned. Meanwhile, the width W₃₀₀ of the metal layer 300, the width W₄₀₀ of the ferroelectric layer 400, and the width W₅₀₀ of the channel layer 500 are larger than a width W₇₀₀ of the gate electrode 700.

Referring to FIG. 9E and FIG. 10E, a gate electrode 200 is formed on the metal layer 300. In some embodiments, the gate electrode 200 in FIG. 9E and FIG. 10E is similar to the gate electrode 200 in FIG. 2B and FIG. 3B, so the detailed description thereof is omitted herein.

Referring to FIG. 9F and FIG. 10F, a second dielectric layer 800 is formed on the first dielectric layer 100 to obtain a second transistor T2E. In some embodiments, the second dielectric layer 800 encapsulates the channel layer 500, the ferroelectric layer 400, the metal layer 300, and the gate electrode 200. In other words, the channel layer 500, the ferroelectric layer 400, the metal layer 300, and the gate electrode 200 are embedded in the second dielectric layer 800. In some embodiments, the second dielectric layer 800 in FIG. 9F and FIG. 10F is similar to the second dielectric layer 800 in FIG. 2F and FIG. 3F, so the detailed description thereof is omitted herein. As illustrated in FIG. 10F, the second dielectric layer 800 is stacked on the first dielectric layer 100.

In some embodiments, with the aids of the hole supply layer 600 and the gate electrode 700, the P-up state can be written in the ferroelectric layer 400 and the erase operation of the memory cell can be easily performed. Therefore, the performance of the memory cell and the second transistor T2E may be enhanced.

In accordance with some embodiments of the disclosure, a transistor includes a first gate electrode, a ferroelectric layer, a channel layer, a second gate electrode, and a hole supply layer. The ferroelectric layer is disposed over the first gate electrode. The channel layer is disposed on the ferroelectric layer. The second gate electrode is disposed over the channel layer. The hole supply layer is located between the second gate electrode and the channel layer. An electron trap density of the hole supply layer is higher than an electron trap density of the channel layer.

In accordance with some embodiments of the disclosure, an integrated circuit includes a substrate, a first transistor, and an interconnect structure. The first transistor is over the substrate. The interconnect structure is disposed on the substrate. The interconnect structure includes dielectric layers and a second transistor embedded in the dielectric layers. The second transistor includes a first gate electrode, a ferroelectric layer, a channel layer, a second gate electrode, and a hole supply layer. The ferroelectric layer is disposed over the first gate electrode. The channel layer is disposed on the ferroelectric layer. The second gate electrode is disposed over the channel layer. The hole supply layer is located between the second gate electrode and the channel layer. An electron trap density of the hole supply layer is higher than an electron trap density of the channel layer.

In accordance with some embodiments of the disclosure, a manufacturing method of a transistor includes at least the following steps. A first dielectric layer is provided. A first gate electrode is formed in the first dielectric layer. A ferroelectric layer and a channel layer are sequentially deposited over the first gate electrode and the first dielectric layer. A hole supply layer and a second gate electrode are formed on the channel layer. An electron trap density of the hole supply layer is higher than an electron trap density of the channel layer. A second dielectric layer is formed to encapsulate the ferroelectric layer, the channel layer, the hole supply layer, and the second gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising:
a first gate electrode;
a ferroelectric layer disposed over the first gate electrode;
a channel layer disposed on the ferroelectric layer;
a second gate electrode disposed over the channel layer; and
a hole supply layer located between the second gate electrode and the channel layer, wherein an electron trap density of the hole supply layer is higher than an electron trap density of the channel layer.

2. The transistor of claim 1, further comprising a metal layer sandwiched between the ferroelectric layer and the first gate electrode.

3. The transistor of claim 1, wherein the second gate electrode extends beyond one edge of the first gate electrode.

4. The transistor of claim 1, further comprising source/drain contacts disposed aside the second gate electrode and the hole supply layer, wherein the source/drain contacts are in physical contact with the channel layer.

5. The transistor of claim 4, wherein the source/drain contacts are located outside of a span of the first gate electrode.

6. The transistor of claim 4, wherein the source/drain contacts are located within a span of the first gate electrode.

7. The transistor of claim 4, wherein one of the source/drain contacts is located within a span of the first gate electrode, and another one of the source/drain contacts is located outside of the span of the first gate electrode.

8. The transistor of claim 1, wherein the hole supply layer covers a bottom surface and sidewalls of the second gate electrode.

9. The transistor of claim 1, wherein a bandgap of the hole supply layer ranges from about 4 eV to about 6 eV.

10. The transistor of claim 1, wherein a material of the hole supply layer comprises HfO₂, TiO₂, Al₂O₃, Si₃N₄, and Ta₂O₅.

11. An integrated circuit, comprising:
a substrate;
a first transistor over the substrate; and
an interconnect structure disposed on the substrate, comprising;
dielectric layers; and
a second transistor embedded in the dielectric layers, comprising:
a first gate electrode;
a ferroelectric layer disposed over the first gate electrode;
a channel layer disposed on the ferroelectric layer;
a second gate electrode disposed over the channel layer; and
a hole supply layer located between the second gate electrode and the channel layer, wherein an electron trap density of the hole supply layer is higher than an electron trap density of the channel layer.

12. The integrated circuit of claim 11, wherein the dielectric layers comprise a first dielectric layer and a second dielectric layer stacked on the first dielectric layer, the first gate electrode is embedded in the first dielectric layer, and the ferroelectric layer, the channel layer, the second gate electrode, and the hole supply layer are embedded in the second dielectric layer.

13. The integrated circuit of claim 12, wherein the second transistor further comprises source/drain contacts penetrating through the second dielectric layer to be in physical contact with the channel layer.

14. The integrated circuit of claim 11, wherein the second transistor further comprises a metal layer sandwiched between the ferroelectric layer and the first gate electrode.

15. The integrated circuit of claim 11, wherein the hole supply layer covers a bottom surface and sidewalls of the second gate electrode.

16. The integrated circuit of claim 11, wherein a bandgap of the hole supply layer ranges from about 4 eV to about 6 eV.

17. A manufacturing method of a transistor, comprising:
providing a first dielectric layer;
forming a first gate electrode in the first dielectric layer;
sequentially depositing a ferroelectric layer and a channel layer over the first gate electrode and the first dielectric layer;
forming a hole supply layer and a second gate electrode on the channel layer, wherein an electron trap density of the hole supply layer is higher than an electron trap density of the channel layer; and
forming a second dielectric layer to encapsulate the ferroelectric layer, the channel layer, the hole supply layer, and the second gate electrode.

18. The method of claim 17, wherein forming the hole supply layer and the second gate electrode comprises:
sequentially depositing a dummy gate dielectric layer and a dummy gate electrode on the channel layer;
encapsulating the dummy gate dielectric layer and the dummy gate electrode by the second dielectric layer;
removing the dummy gate dielectric layer and the dummy gate electrode to form an opening in the second dielectric layer; and
depositing the hole supply layer and the second gate electrode in the opening of the second dielectric layer.

19. The method of claim 17, further comprising:
forming a metal layer between the first gate electrode and the ferroelectric layer.

20. The method of claim 17, further comprising:
forming source/drain contacts on the channel layer, wherein the source/drain contacts penetrate through the second dielectric layer.
